(19) United States
(12) Patent Application Publication
(10) Pub. No.: US 2011/0083731 A1
(43) Pub. Date: Apr. 14, 2011

(54) Solar-cell device with efficiency-improving nanocoating and method of manufacturing thereof

(75) Inventors: Oleg Nikolaevich Gadomsky, Ulianovsk (RU); Nikolai Mikhailovich Ushakov, Saratov (RU); Igor Donatovich Kosobudsky, Saratov (RU); Vitaly Yakovlevich Podvigalkin, Saratov (RU)

(73) Assignee: Gaze Nanotech Corp, Oleg gadomsky, Arkady Zeyde, Igor Shtutman, Igor Voltovsky

(21) Appl. No.: 12/587,672

(22) Filed: Oct. 9, 2009

(51) Int. Cl. H01L 31/00; H01L 31/18

(52) U.S. Cl. 136/256; 438/72; 257/E21.211

(57) ABSTRACT

A solar cell device of improved efficiency consists of a photovoltaic solar cell and an efficiency-improving antireflective nanocoating film that is applied on the solar cell and interacts with the photovoltaic process of the cell. The coating film has a thickness ranging from 100 nm to 100 μm, and comprises a dielectric material that contains metal nanoparticles having dimensions from 4.5 to 10 nm and concentration ranging from 1 to 5%. The effect of improved efficiency is presumably obtained due to organization of nanoparticles into specific clusters. The method of manufacturing the solar-cell device of the invention comprises preparation of the polymer solution that contains uniformly dispersed metal nanoparticles of silver, gold, or another diamagnetic metal and forming the aforementioned coating film by heat-treating and drying the applied solution under specific conditions.

### FIELD OF THE INVENTION

The present invention relates to solar cell devices consisting of solar cells with antireflective coatings, and specifically, to aforementioned solar cells with specific nanostructured coatings that enhance the photovoltaic effect inherent in such solar cells.

### BACKGROUND OF THE INVENTION

The main trend in contemporary solar cells is improvement of their efficiency, and this trend is carried out in the following two directions: (1) development of new photoelectronic, e.g., semiconductor, structures aimed at improving the efficiency of conversion of light energy into electricity in the cell, per se; and (2) development of auxiliary means for more efficient delivery of light into the solar cell.

Known in the art are already several generations of solar cells that differ from each other by gradual improvement of their efficiency. In spite of the fact that solar-cell structures based on the use of amorphous silicon relate to the first generation and have relatively low efficiency (6 to 9 percent), they are still widely used and find practical application due to their low manufacturing cost (when compared with the latest generation of solar cells) and well established production facilities with well developed production techniques.

Hereinafter the term “first-generation solar cells” covers solar cells based on the use of amorphous silicon.

It is understood that a significant breakthrough could be achieved if it were possible to combine low cost and structural simplicity of first-generation solar cells with new techniques capable of drastically improving their efficiency to the level of the latest generation of devices (with efficiency of 30% or higher).

One of the main problems encountered by solar cells is reflection of incident light. In an attempt to increase the amount of light at the desired wavelength to reach the surface of the solar cell, an antireflective coating is generally added to the cell, thus forming solar-cell devices, or assemblies.

An antireflective coating is a coating that has a very low coefficient of reflection. The antireflection coating reduces unwanted reflections from surfaces and is commonly used on eyeglasses and photographic lenses.

Whenever a ray of light moves from one medium to another (e.g., when light enters a sheet of glass after traveling through air), some portion of the light is reflected from the surface (known as the interface) between the two media. The strength of the reflection depends on the refractive indices of the two media as well as the incidence angle. The exact value can be calculated using Fresnel equations.

When light meets the interface at normal incidence (i.e., perpendicularly to the surface), the intensity of separated light is characterized by the reflection coefficient, or reflectance, R:

$$R = {( \frac{{n}_{0} - {n}_{S}}{{n}_{0} + {n}_{S}} )}^{2}$$

where n₀ and n_{S} are refractive indices of the first and second media, respectively. The value of R varies from 0.0 (no reflection) to 1.0 (all light reflected) and is usually quoted as a percentage. Complementary to R is the transmission coefficient, or transmittance, T. If the effects of absorption and scatter are neglected, then the value T is always 1−R. Thus, if a beam of light with intensity I is incident on the surface, a beam of intensity RI is reflected, and a beam with intensity TI is transmitted into the medium.

For a typical situation with visible light traveling from air (n₀≈1.0) into common glass (n_{S}≈1.5), the value of R is 0.04, or 4%. Thus, only 96% of the light (T=1−R=0.96) actually enters the glass, and the rest is reflected from the surface. The amount of light reflected is known as reflection loss. Light may also bounce from one surface to another multiple times, being partially reflected and partially transmitted each time it does so. In all, the combined reflection coefficient is given by 2R/(1+R). For glass in air, this is approximately 7.7%.

For a single-layer coating of glass, the light ray reflects twice, once from the surface between air and the layer, and once from the layer-to-glass interface.

From the equation above with refractive indices being known, reflectivities for both interfaces can be calculated and denoted R₀₁ and R_{1S}, respectively. The transmission at each interface is therefore T₀₁=1−R₀₁ and T_{1S}=1−R_{1S}. Total transmittance into the glass is thus T_{1S}T₀₁. Calculating this value for various values of n₁, it can be found that at one particular value of optimum refractive index of the layer, the transmittance of both interfaces is equal, and this corresponds to the maximum total transmittance into the glass.

This optimum value is given by the geometric mean of the two surrounding indices:

n₁=\sqrt{n₀nₛ}

For the example of glass (n_{S}≈1.5) in air (n₀≈1.0), this optimum refractive index is n₁≈1.225. The reflection loss of each interface is approximately 1.0% (with a combined loss of 2.0%), and an overall transmission T_{1S}T₀₁ is approximately 98%. Therefore an intermediate coating between air and glass can reduce the reflection loss by half of its normal (uncoated) value.

Practical antireflection coatings, however, rely on an intermediate layer not only for direct reduction of reflection coefficient but also on use of the interference effect of a thin layer. Assume that the layer thickness is controlled precisely such that it is exactly one-quarter of the wavelength of light depth (λ/4), forming a quarter-wave coating. If this is the case, the incident beam I, when reflected from the second interface, will travel exactly half its own wavelength farther than the beam reflected from the first surface. If intensities of the two beams, R₁ and R₂, are exactly equal, then since they are exactly out of phase, they will destructively interfere and cancel each other. Therefore, there is no reflection from the surface, and all energy of the beam must be in the transmitted ray, T.

Real coatings do not reach perfect performance, though they are capable of reducing the reflection coefficient of a surface to less than 0.1%. Practical details include correct calculation of layer thickness; since the wavelength of light is reduced inside a medium, this thickness will be λ₀/4n₁, where λ₀ is the vacuum wavelength. Also, the layer will be the ideal thickness for only one distinct wavelength of light. Other difficulties include finding suitable materials because few useful substances have the required refractive index (n≈1.23) that will equalize the intensity of both reflected rays. Magnesium fluoride (MgF₂) is often used because it is hard-wearing and can be easily applied to substrates using physical vapor deposition, even though its index is higher than desirable (n=1.38).

Further reduction is possible by using multiple coating layers, designed such that reflections from the surfaces undergo maximum destructive interference. One way to do this is to add a second quarter-wave-thick higher-index layer between the low-index layer and the substrate. The reflection from all three interfaces produces destructive interference and antireflection. Other techniques use varying thicknesses of coatings. By using two or more layers, each material is chosen to give the best possible match of desired refractive index and dispersion. Broadband antireflection coatings that cover the visible range (400-700 nm) with maximum reflectivities of less than 0.5% are commonly achievable.

The exact nature of the coating determines the appearance of the coated optics; common antireflective coatings on eyeglasses and photographic lenses often look somewhat bluish (since they reflect slightly more blue light than other visible wavelengths), though green-tinged and pink-tinged coatings are also used.

If the coated optic is used at non-normal incidence (i.e., with light rays not perpendicular to the surface), antireflection capabilities are degraded somewhat. This occurs because a beam traveling through the layer at an angle “sees” a greater thickness of the layer. There is a counter-intuitive effect at work here; although the optical path taken by light is indeed longer, interference coatings work on the principle of “difference in optical-path length” or “phase thickness” because light tends to be coherent over a very small (tens to hundreds of nm) thickness of the coating. The net effect is an antireflection band of coating that tends to move to shorter wavelengths as the optic is tilted. Coatings can also be designed to work at a particular angle; beam splitter coatings are usually optimized for 45° angles. Non-normal incidence angles also usually cause reflection to be polarization dependent.

Known in the art are methods of imparting antireflective properties to optical devices by coating them with single-layered or multilayered interferential coatings.

Application of N sequential layers provides 2N parameters (i.e., N refractive indices and N thicknesses). Such a coating makes it possible to efficiently suppress reflection in a predetermined angular range by selecting predetermined combinations of reflective indices and thicknesses. Thus, at high angles of incidence for N wavelengths, the coefficient of reflection from the coating can be reduced to [a value close to] zero. By arranging the minimums of reflection over the spectrum, it becomes possible to obtain a coating with a predetermined integral reflective capacity. In order to obtain an antireflective coating with efficient achromatization, it is necessary to have a wide assortment of substances differing in dispersions and indices of refraction. Therefore, an essential problem associated with improvement of interferential coatings is broadening of the assortment of transparent substances suitable for application onto substrates in the form of homogeneous films [M. Born and E. Wolf, Principles of Optics, Pergamon Press, 1968, Chapter 1.]

Thus, known methods of forming antireflective coatings possess the following disadvantages.

(1) They cannot provide minimal reflective capacity in a wide range of wavelengths of visible light spectrum, i.e., from 400 nm to 800 nm, and in a wide range of angles of incidence 0 to 90°.

(2) Known processes are limited in the choice of substances for application of alternating layers. These substances must be transparent in the visible part of the optical spectrum; films made from these substances must be homogeneous and possess appropriate mechanical properties and high adhesive capacity.

(3) Widening of an antireflection spectrum requires an increase in the number of layers, and this leads to accelerated aging of interferential coatings.

(4) Known interferential antireflective coatings do not provide minimal reflection in a wide range of wavelengths and incidence angles when such coatings are applied onto surfaces of opaque media.

(5) A common disadvantage of conventional interferential coatings is that their structure, properties, and design must always be considered with reference to the nature, properties, and characteristics of the substrate onto which the coating is applied.

Recent development of nanotechnology opened a new avenue for improving properties of coatings based on the use of new physical phenomena inherent only to nanostructures. Nanometer-scaled layers and structures are becoming more and more important in optics and photonics. Very thin layers are routinely used as antireflective coatings for displays, lenses, and other optical elements. High-grade antireflective coatings can be created using nanoporous polymer films. Ultrathin layers are being increasingly used in solar-cell devices and are a key element in the realization of large and brilliant displays based on organic light-emitting diodes (OLEDs) merged with nanoparticle coatings. Tiny nanoclusters make possible not only silicon-based light emission, which can be used in optocouplers, but also novel sensor devices and integrated optical systems.

The patterning of nanoparticles for controlling optical properties of coatings is known. For example, U.S. Patent Application Publication No. 20050118411 (inventor C. Horne) published in 2005 describes nanoscale particles, particle coatings/particle arrays, and corresponding consolidated materials based on an ability to vary the composition involving a wide range of metal and/or metalloid elements and corresponding compositions. In particular, metalloid oxides and metal-metalloid compositions are described in the form of improved nanoscale particles and coatings formed from the nanoscale particles. Compositions comprising rare earth metals and dopants/additives with rare earth metals are described. Complex compositions with a range of host compositions and dopants/additives can be formed using the approaches described. Particle coating can take the form of particle arrays that range from collections of disbursable primary particles to fused networks of primary particles forming channels that reflect the nanoscale of the primary particles. Suitable materials for optical applications are described along with some optical devices of interest.

This new technique is based on the fact that when nanoparticles of certain metals or dielectrics are introduced into coating layers, the nanoparticles change or improve properties. In the field of optical coatings, the technique based on the use of nanoparticles is used as a new approach for obtaining antireflective coatings that impart new properties to optical elements, e.g., optical filters. Introduction of the aforementioned new technique makes it possible to improve quality and to reduce the number of coating layers.

U.S. Patent Application Publication 2009/0025777 published Oct. 29, 2009 (inventor D. Varaprasad) discloses a method of making an antireflective silica coating by forming a silica precursor having a radiation-curable composition including a radiation-curable monomer and/or a photoinitiator, and also including a silica sol comprising silane and/or colloidal silica. The silica precursor can be deposited on a substrate (e.g., glass substrate or silicon wafer) to form a coating layer. The coating layer may then be cured by means of exposure to electromagnetic radiation, such as UV radiation. Then, the cured coating layer may be fired using temperature(s) of 550° C. to 700° C. to form the low-index silica-based coating. The low-index silica-based coating can be used as an antireflective (AR) film on a front-glass substrate of a solar-cell device.

U.S. Pat. No. 7,394,016 issued Jul. 1, 2008 to C. Gronet discloses a solar-cell device comprising a plurality of elongated solar cells, wherein each respective internal reflector in the plurality of internal reflectors is configured between a first and second elongated solar cell in the plurality of elongated solar cells such that a portion of solar light reflected from the respective internal reflector is reflected onto the corresponding first and second elongated cell.

U.S. Pat. No. 6,107,564 issued Aug. 22, 2000 to J. Aguilera, et al., discloses an ultraviolet and infrared reflecting coating with a wide transmission band and a solar-cell cover on which the coating has been deposited. The coating contains a multilayer bandpass filter, and some of the layers of this filter are comprised of mixed materials that have a selectable index of refraction. The design can be optimized by varying the index or refraction of at least one of the layers of mixed material.

All patent examples given above relate to attempts to improve efficiency of solar cells by introducing respective antireflective coating into solar-cell design and by rearranging various reflective layers and surfaces.

However, as mentioned above, a disadvantage of such an approach is that at angles of light incidence that are far from normal, one reflection can become so high that it cannot be efficiently reduced by any antireflective coating. Therefore a major part of light incident at skewed angles to the surface remains unused. One method of solving this problem is providing the solar cell with a system for tracing the position of the sun and for automatically changing the angle of incidence depending on the position of the light-receiving surface to the sun. It is understood that this leads to significant increase in cost of the solar cell.

Another way of partially solving the above problem is providing a solar cell with a specially structured surface. For example, U.S. Patent Application Publication 20090071537 published in 2009 (inventors O. Yavuzcetin, et al) discloses an antireflective layer solar cell/optical medium formed by nanostructuring the surface of the optical material into which light transmission is desired. The surface of the optical material is etched through a nanoporous polymer film etch mask to transfer the porous pattern to the optical material. The resultant nanostructured layer is an optical meta-material since it contains structural features much smaller than the wavelength of light, and the presence of these structural features changes the effective index of refraction by controlling the degree of porosity in the nanostructured layer and the thickness of the porous layer.

Other methods of arranging nanoparticles into nanostructures are described, e.g., in European Patent Application Publication EP 1510861A1 published Feb. 3, 2003 (inventors O. Harnack, et al); U.S. Patent Application Publication 2006/0228491A1 published Oct. 12, 2006, (inventors M. Choi, et al), etc.

However, all solar panels with antireflective coatings described above and known to the inventors herein do not improve the efficiency of solar cells and act only passively, i.e., without affecting the photoelectronic processes of the cell. In other words, all existing structures and methods do not provide a breakthrough in the improvement of solar-cell efficiency and only insignificantly improve this characteristic at the expense of complexity of structure and increase in manufacturing cost. In other words, the inventors herein are not aware of any published material teaching that interaction between patterned and closely arranged nanoparticles can be used to reduce reflection in antireflective coatings of solar cells in order to improve their efficiency.

### SUMMARY OF THE INVENTION

The inventors herein have developed a dielectric coating with metal nanoparticles of predetermined dimensions combined into specific clustered structures and uniformly dispersed in the dielectric matrix. It was unexpectedly found that when the newly developed coating film is applied onto a solar cell and when the film possesses predetermined parameters, the efficiency of the coated solar cells sharply increases. The inventors called this phenomenon a “giant photovoltaic effect.” The aforementioned parameters that affect the giant photovoltaic effect are the following: (1) material of the dielectric matrix; (2) material of the metal nanoparticles; (3) nanoparticle dimensions; (4) concentration of metal nanoparticles in the dielectric matrix material; (5) film thickness; and (6) arrangement of metal nanoparticles in the dielectric matrix material.

Dielectric materials, such as polymers, were tested as the matrix material of the coating film. The study has shown that the matrix material should have a predetermined dielectric constant. Although different materials can be used as a matrix material, the following description will be made with reference to poly(methyl methacrylate) (hereinafter referred to as PMMA). It is understood that the invention is not limited to this specific material. In fact, the dielectric material of the film matrix can comprise polyethylene, polytetraphthoroethylene, etc. However, testing of these materials showed that they are unsuitable for efficient use as the matrix of the coating film of the invention and that they are inferior to PMMA in this function. For example, one of the important technical requirements of the coating of the invention is stabilization of metal nanoparticle surfaces. Tests conducted by the inventors showed that matrices other than PMMA, e.g., polyethylene, are too loose and cannot protect the surfaces of silver nanoparticles from oxidation, the composite film having acquired an undesirable yellow-brown color.

Metals that were investigated for the purposes of the invention comprised gold, silver, chromium and other preferably diamagnetic metals of high conductivity. Coating that contains silver nanoparticles as an example of a metal suitable for the invention will be described herein. Silver nanoparticles that showed the most optimal results in obtaining the giant photovoltaic effect had dimensions ranging from 4.5 to 10 nm. The most optimal concentration of diamagnetic metal nanoparticles appeared to be in the range of 1 to 5 wt. %, and the highest giant photovoltaic effect was observed at 3 wt. % of silver in the PMMA matrix. Film thickness can vary from 100 nm to 100 μm.

According to one aspect of the invention, a photovoltaic solar-cell device is produced by the following method. First, a metal-containing polymer solution is prepared. A reactor is filled with oil and a dosed amount of a polymer. The reactor is then filled with an inert gas, e.g., argon, which is preliminarily cleared from oxygen and nitrogen. The mixture is heated while being intensively stirred.

The synthesis temperature is selected in the range of 110 to 250° C. and controlled with accuracy of ±5° C. A solution of a metal-containing compound is then introduced dropwise into the molten polymer. Gaseous products of the reaction are removed by purging the reactor with inert gas. The reaction product is filtered out, and the viscous product is extracted with a solvent, e.g., benzol, for several hours. The product is dehydrated and dried, whereby a powdered composite material is obtained. The color of the powdered composite material depends on the nature and concentration of the metal particles as well as on synthesis conditions.

Samples of coating films of composite materials for application onto the photovoltaic solar cell were prepared with different concentrations of metal nanoparticles of different dimensions. Coating films were obtained with a thickness of 10 μm to 100 μm. Metal (silver) particles had concentration in the range of 1 to 20 wt. % per weight of the matrix materials.

A photovoltaic solar-cell device of the invention consists substantially of the following main components: a substrate made, e.g., of glass; a current take-off electrode placed onto the glass substrate; a p-type silicon plate placed onto the current take-off electrode; an n-type silicon plate; a metal framing with front contacts placed onto the n-type silicon plate; and a dielectric coating having a thickness of 10 μm to 100 μm metal nanoparticles, e.g., silver nanoparticles having concentration of 1 to 20 wt. % per weight of the matrix materials, preferably 2 to 4 wt. %, and most preferably 3 wt. %. The metal nanoparticles should have dimensions of 4 to 10 nm. The matrix material of the coating film can comprise conventional dielectrics transparent in a visible range of the light spectrum, such as glass, polymers, ceramics, glass-ceramics, etc.

The photovoltaic solar cell of the invention was tested with the use of a photocell specimen composed of four sequentially arranged sections and a diaphragm plate for measuring photo response in each section. The first section was a photocell coated with a combined metal-polymer film of the invention. The second and third sections were photocells without a coating; and the fourth section was a photocell coated with the same composite metal-polymer film as the first section. The diaphragm plate was made from a light-impermeable material, with a diaphragm opening in the area distant from the edges for eliminating a boundary effect when the specimen surface was illuminated. The photocell sections were illuminated under equal light flow conditions, with white light having spectral characteristics close to solar one.

Measurements were carried out by using a simple measurement circuit that contained a voltmeter, an ammeter, and a loading resistor. The circuit made it possible to measure current generated by the photovoltaic solar cell under no-load and load conditions. The no-load condition means that resistor R was disconnected by means of a switch. A light source for the test comprised a conventional halogen lamp with a light spectrum close to solar rays and a light guide that allowed experiments with collimated light, i.e., light beams created with divergence limited only by diffraction.

The tests showed that optimal conditions were obtained with concentration of metal at 3-wt % and a film thickness of 70 μm.

The giant photovoltaic effect developed in the silicon solar-cell device of the invention coated with a composite polymer-3% metal film reached the following efficiency:

η=67.45%

The exact mechanism of the giant photovoltaic effect provided by solar-cell devices of the invention coated with the above-described composite metal-polymer films is not known, but the inventors herein assume that the effect results from a specific configuration of metal particles that the inventors refer to as “a cluster structure.” Nanoparticles in a cluster are spherical, and they are tightly packed and have the same size. Each cluster is composed of 21 particles. It is these particular clusters that are capable of providing the “giant photovoltaic effect.”

The composite metal-polymer film has a thickness in the range of 10 to 100 μm. The composite film technique developed by the inventors makes it possible to obtaift very thin films with a thickness on the order of 100 nm.

Transmission spectra through a 50 μm-thick clean polymer film on a glass substrate and through the same film on the same substrate but with 10% metal content in the film showed that for the film of the invention, transmittance T was close to 1. In other words, it was found that introduction of metal nanoparticles having the above-described arrangement in polymer film converted this film into a super-transparent medium having in a wide range of the optical spectrum an absorption index on the order of 10⁻⁴. Further, it is important to note that the coating film of the invention did not change the spectra of initial irradiation. The film provided a coefficient of refraction equal to 0.039. The inventors calculated this value from the measured coefficient of reflection.

The principle of wideband antireflection on the basis of new and transparent optical materials with quasi-zero values of indices of refraction and absorption is possible when the following condition is fulfilled.

$${r}_{12} = - {r}_{23} exp ( \frac{4 π}{λ} {n}_{2} {d}_{2} ) \vert$$

where in case of incidence of external light in the direction perpendicular to the surface, Frenel coefficients are expressed as follows.

$${r}_{12} = \frac{{n}_{1} - {n}_{2}}{{n}_{1} + {n}_{2}} , {r}_{23} = \frac{{n}_{2} - {n}_{3}}{{n}_{2} + {n}_{3}}$$

When absorption and refraction indices of a film from new (metal-polymer) materials reach zero values, such films can provide conditions of the ideal optical refraction on the surfaces of optical media. The following condition of ideal optical refraction is determined from the above equation.

$${r}_{12} = - {r}_{23} exp ( \frac{4 π}{λ} {n}_{2} {d}_{2} ) \vert$$

Under conditions of ideal optical antireflection, the amplitude of a reflected wave, and, hence, the reflective capacity of the semi-infinitive medium surface, turns to zero.

Under conditions of ideal optical antireflection, the amplitude of an optical wave that penetrates the substrate is equal to the amplitude of the external wave under any angle of incidence.

If the substrate is transparent, i.e., comprises a low-absorption medium, then under conditions of ideal optical antireflection, a composite metal-polymer film becomes super-transparent, i.e., invisible to the viewer who looks at the film from above.

If the medium is absorptive, then under conditions of ideal optical antireflection, a viewer who looks at the coating film from above will perceive the substrate as a black body.

Under conditions of ideal optical antireflection, optical properties of an antireflective coating do not depend on optical properties of a substrate. This means that such an antireflective coating is universal and can be used to impart antireflective properties to surfaces of media made from various materials, including those with strong dispersion dependence on the dielectric constant.

Taking into account optical properties of the obtained composite metal-polymer film, it can be stated that nanomaterials of a new class can be synthesized, wherein by changing the arrangement of nanoparticles in the polymer film, it becomes possible to change the refraction index in a very wide range.

The giant photovoltaic effect observed by the inventors is based on the use of composite metal-polymer films that possess a low refraction index n and a low absorption index “k”. In other words: n≈0, k≈0

Thus, it has been shown that the invention provides a photovoltaic solar-cell device with a nanostructured coating that drastically improves efficiency of the photovoltaic solar-cell device due to active interaction of elements of the nanostructured coating with photoelectronic processes that occur in the photovoltaic solar-cell device. The invention also provides a method for manufacturing a photovoltaic solar cell of high efficiency by coating the surface of a solar cell with a special coating that leads to a giant improvement in the efficiency of solar cells and that is universal for solar cells of different types.

### BRIEF DESCRIPTION OF THE DRAWINGS

FIG. 1 is a sectional view of a solar-cell device of the invention with efficiency-improving nanocoating.

FIG. 2 is a plan view of photocell specimen used for test of the solar cell of the invention.

FIG. 3 is a plan view of a diaphragm plate use for test of the solar cell of the invention.

FIG. 4 is a graph that shows results of measurements of particle-size dispersion conducted for the most efficient coatings.

FIG. 5 is a model of a cluster structure into which the nanoparticles are packed in the coating layer of the invention.

FIG. 6 is a graph that shows transmission spectra through a 50 μm-thick clean polymer film on a glass substrate and through the same film on the same substrate but with 10% metal content in the film of the invention.

FIG. 7 is a graph which shows a curve that corresponds to irradiation of a receiver, per se; a curve that corresponds to a 50-micron-thick metal-polymer coating film on a glass substrate having a thickness of 1 mm, a curve that corresponds to a 10-micron-thick metal-polymer coating film on a glass substrate having a thickness of 1 mm, and a curve that corresponds to a glass substrate having a thickness of 1 mm and having no coatings.

FIGS. 8 and 9 are graphs that show dependence of reflectance from the wavelength obtained for the coating films of the invention.

### DETAILED DESCRIPTION OF THE INVENTION

In an attempt to find a coating that could significantly improve efficiency of a photovoltaic solar cell device due to improvement of antireflective properties, the inventors herein discovered an unexpected effect of improving the efficiency of a photovoltaic solar-cell device by using a nanostructured coating of the type earlier invented by O. Gadomsky, one of the inventors of the present application and disclosed in published U.S. Patent Application Publication 20080171192 published Jul. 17, 2008. More specifically, the above-mentioned publication discloses an antireflective coating applied onto a substrate in the form of at least one layer of nanoparticles arranged on the aforementioned substrate at equal distances from each other in accordance with a specific nanostructure. The nanoparticles are made from a material that under effect of incident light generates between the neighboring particles optical resonance interaction with a frequency that belongs to the visible optical range. Interaction between the nanoparticles reduces reflection of incident light. The nanoparticles have a radius in the range of 10 to 100 nm and a pitch between the adjacent particles that ranges between 1.5 diameters to several diameters.

However, although the coating of published U.S. Patent Application Publication 20080171192 was superior to conventional interference-type antireflective coating, this coating still did not show any drastic improvement in antireflective efficiency. Furthermore, application of such coatings to the surface of photovoltaic solar cells did not essentially improve photovoltaic solar-cell efficiency, although some small improvement was observed.

In an attempt to further improve photovoltaic solar-cell efficiency, the inventors herein developed a dielectric coating with metal nanoparticles of predetermined dimensions uniformly dispersed in the dielectric matrix. The inventors unexpectedly found that when the newly developed coating film is applied onto a photovoltaic solar cell and when the film possesses predetermined parameters, efficiency of the coated photovoltaic solar cells sharply increases. The inventors called this phenomenon a “giant photovoltaic effect.” The aforementioned parameters that affect the giant photovoltaic effect are the following: (1) material of the dielectric matrix; (2) material of the metal nanoparticles; (3) nanoparticle dimensions; (4) concentration of metal nanoparticles in the dielectric matrix material; (5) film thickness; and (6) arrangement of metal nanoparticles in the dielectric matrix material.

Dielectric materials, such as polymers, were tested as the matrix material of the coating film. The study has shown that the matrix material should have a predetermined dielectric constant.

Although different materials can be used as a matrix material, the following description will be made with reference to poly(methyl methacrylate) (hereinafter referred to as PMMA). It is understood that the invention is not limited to this specific material. In fact, dielectric material of the film matrix can comprise polyethylene, polytetraphthoroethylene, etc. However, testing of these materials showed that they are unsuitable for efficient use as the matrix of the coating film of the invention and that they are inferior to PMMA in this function. For example, one of important technical requirements of the coating of the invention is stabilization of metal nanoparticle surfaces. The tests conducted by the inventors showed that matrices other than PMMA, e.g., polyethylene, are too loose and cannot protect the surfaces of silver nanoparticles from oxidation, the composite film having acquired an undesirable yellow-brown color.

Metals that were investigated for the purposes of the invention comprised gold, silver, chromium, and other preferably diamagnetic metals of high conductivity. Coating that contains silver nanoparticles as an example of a metal suitable for the invention will be described herein. Silver nanoparticles that showed optimal results in obtaining the giant photovoltaic effect had dimensions ranging from 4.5 to 10 nm. The optimal concentration of diamagnetic metal nanoparticles appeared to be in the range of 1 to 5 wt. %, and the highest giant photovoltaic effect was observed at 3-wt. % of silver in the PMMA matrix. Film thickness can vary from 100 nm to 100 μm.

According to one aspect of the invention, a photovoltaic solar-cell device with efficiency-improving nanocoating is produced according to the following method. First, a metal-containing polymer solution is prepared. For this purpose, a reactor is filled with oil and a dosed amount of a polymer. The reactor is then filled with an inert gas, e.g., argon, which is preliminarily cleared from oxygen and nitrogen. The mixture is heated while being intensively stirred. The synthesis temperature is selected in the range of 110 to 250° C. and controlled with accuracy of ±5° C. A solution of a metal-containing compound is then introduced dropwise into the molten polymer. Gaseous products of the reaction are removed by purging the reactor with inert gas. The reaction product is filtered out, and the viscous product is extracted with a solvent, e.g., benzol, for several hours. The product is dehydrated and dried, whereby a powdered composite material is obtained. The color of the powdered composite material depends on the nature and concentration of the metal particles as well as on synthesis conditions.

Samples of coating films of composite materials for application onto the photovoltaic solar cell were prepared with different concentrations of metal nanoparticles of different dimensions. Coating films were obtained with a thickness of 10 μm to 100 μm. Metal (silver) particles had concentration in the range of 1 to 20 wt. % per weight of the matrix materials.

A photovoltaic solar cell is a device that converts light directly into electricity by means of the photovoltaic effect. Sometimes the term “solar cell” is reserved for devices intended specifically for capturing energy from sunlight, while the term “photovoltaic cell” is used when the light source is unspecified. Assemblies of cells are used to make solar panels, solar modules, or photovoltaic arrays. Photovoltaics is the field of technology and research related to the application of solar cells in producing electricity for practical use. The energy generated in this way is an example of solar energy (also called solar power).

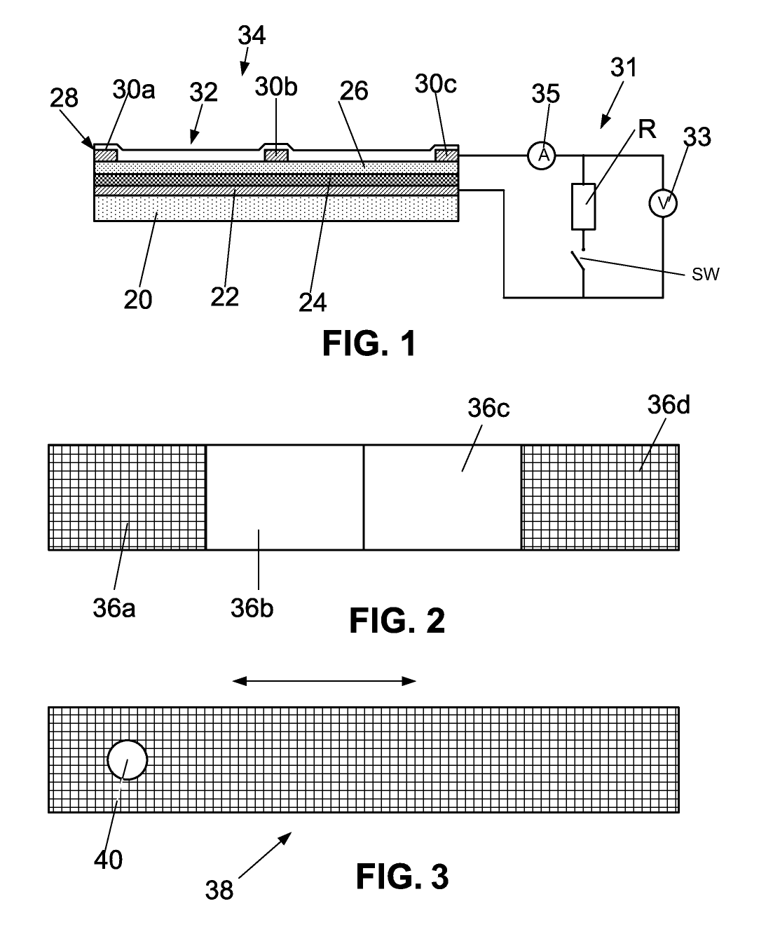

A solar-cell device of the invention with efficiency-improving nanocoating is shown in FIG. 1. The solar cell of the invention, which as a whole is designated by reference numeral 18, consists substantially of the following main components: a substrate 20 made, e.g., of glass; a current take-off electrode 22 placed onto the glass substrate; a p-type silicon plate 24 placed onto the current take-off electrode; an n-type silicon plate 26; a metal framing 28 with front contacts 30a, 30b, and 30c placed onto the n-type silicon plate 26; and a dielectric coating 32 having a thickness of 10 μm to 100 μm with metal nanoparticles, e.g., silver nanoparticles having concentration of 1 to 20 wt. % per weight of the matrix materials, preferably 2 to 4 wt. %, and most preferably 3 wt. %. The metal nanoparticles should have dimensions of 4 to 10 nm. The matrix material of the coating film 32 can comprise conventional dielectrics transparent in a visible range of the light spectrum, such as glass, polymers, ceramics, glass-ceramics, etc. In FIG. 1, reference numeral 34 designates a light beam with spectral characteristics close to those of solar beams.

The following describes the operation of the solar-cell device 18 with reference to the nanostructured coating film 32, which constitute the main components of the solar-cell device 18.

Energy-conversion efficiency of a solar-cell device is the percentage of converted power (from absorbed light to electrical energy) collected when a solar-cell device is connected to an electrical circuit. Energy conversion is calculated using the ratio of maximum power (Pₘ) divided by input light irradiance (E, in W/m²) under standard test conditions (STC) and the surface area of a solar cell device (A_{c} in m²).

$$η = \frac{{P}_{m}}{{EA}_{c}}$$

Standard test conditions specify a temperature of 25° C. and an irradiance of 1000 W/m² with a 1.5 (AM1.5) air-mass spectrum. This corresponds to the irradiance and spectrum of sunlight incident on a clear day upon a sun-facing 37°-tilted surface with the sun at an angle of 41.81° above the horizon. This condition approximately represents solar noon near the spring and autumn equinoxes in the continental United States, with the surface of the cell aimed directly at the sun. Thus, under these conditions, a solar-cell device of 12% efficiency with a 100-cm² (0.01 m²) surface area can be expected to produce approximately 1.2 Watts of power. It should be noted that the inventors conducted their test under conditions close to those described above.

A photocurrent of an uncoated solar-cell device is the following.

$${I}_{ph}^{( 0 )} = {T}^{( 0 )} ( λ ) Q ( λ ) \frac{λ}{1.24} {P}_{0}$$

where T⁽⁰⁾(λ) is transmissivity of the surface, Q(λ) is quantum output, λ is wavelength, and P₀ is incident optical power.

Electrical power of an uncoated photocell loaded with load R_{N} is expressed as follows.

Pₑ⁽⁰⁾=(Iₚₕ⁽⁰⁾)²R_{N}

Efficiency of an uncoated solar cell is expressed as follows.

$${η}_{0} = {{R}_{N} ( {T}^{( 0 )} ( λ ) )}^{2} {Q}^{2} ( λ ) {( \frac{λ}{1.24} )}^{2} {P}_{0}$$

Efficiency of a solar cell coated with a film is expressed as follows.

$$η = {{R}_{N} ( T ( λ ) )}^{2} {Q}^{2} ( λ ) {( \frac{λ}{1.24} )}^{2} {P}_{0}$$

where T(λ) is transmissivity through the surface of a film-coated solar cell.

The ratio of efficiencies can be expressed as follows.

$$\frac{η}{{η}_{0}} = \frac{{( T ( λ ) )}^{2}}{{( {T}^{( 0 )} ( λ ) )}^{2}}$$

In a silicon-solar cell device:

T⁽⁰⁾≈0.65 and (T⁽⁰⁾)²≈0.4335

If T=1+A−R, where R is reflective capacity and A is relative intensity of the optical field inside a composite film, then at R≈0, the following can be written.

η/η₀>>1

The test was carried out with the use of a photocell specimen 36 shown in FIG. 2. The specimen 36 is composed of four sequentially arranged sections 36a, 36b, 36c, and 36d and a diaphragm plate 38 shown in FIG. 3. The diaphragm is intended to measure photo response in each section. The first section 36a is a photocell coated with the combined metal-polymer film of the invention, such as the film 32 shown in FIG. 1. The second and third sections 36b and 36c are photocells without coating; and the fourth section 36d is a photocell coated with the same composite metal-polymer film as used in the first section 36a. The diaphragm plate 38 is made from a light-impermeable material with a diaphragm opening 40 in the area distant from the edges for eliminating a boundary effect when the specimen surface is illuminated. The photocell sections 36a, 36b, 36c, and 36d are illuminated under equal light-flow conditions, with white light having spectral characteristics close to solar one.

Table 1 shows measurement results of voltage (mV) generated by a photovoltaic solar cell before and after application of the coating film without application of a load. Table 2 shows measurement results of voltage (mV) generated by a solar cell before and after application of the coating film with application of a load. Measurements were carried out by using a simple measurement circuit 31, shown in FIG. 1. This circuit is connected to the output terminals of the photovoltaic solar cell 34, i.e., to the front electrode 30c and the output electrode plate 22. The circuit contains a voltmeter 33, an ammeter 35, and a loading resistor R. The circuit 31 makes it possible to measure current generated by the photovoltaic solar cell 34 under no-load and load conditions. The no-load condition means that the resistor R is disconnected by means of a switch SW. A light source for the test comprised a conventional halogen lamp with a light spectrum close to solar rays and a light guide that allowed experiments with collimated light, i.e., light beams created with divergence limited only by diffraction.

TABLE 1

| | Collimated light | | |
|---|---|---|---|
| | First | Second | Average |
| | measurement | measurement | measurement |
| Type of coating film | (mV) | (mV) | (mV) |
| Photovoltaic solar cell with polymer + | 62 | 56 | 59 |
| metal (10 wt. %), 50-μm film | | | |
| Photovoltaic solar cell with film of | 22 | 18 | 20 |
| polymer without metal | | | |
| Photovoltaic solar cell with Polymer + | 114-140 | 126 | 126 |
| metal (3 wt. %), 70-μm film | | | |
| Photovoltaic solar cell without coating | 5 | 6 | 5.5 |
| film | | | |
| Photovoltaic solar cell with Polymer + | 22 | 26 | 24 |
| metal (1 wt. %), 60-μm film | | | |

TABLE 2

| | Collimated light | | |
|---|---|---|---|
| | First | Second | Average |
| | measurement | measurement | measurement |
| Type of coating film | (mV) | (mV) | (mV) |
| Photovoltaic solar cell with Polymer + | 60 | 58 | 59 |
| metal (10 wt. %), 50-μm film | | | |
| Photovoltaic solar cell with film of | 30 | 28 | 29 |
| polymer without metal | | | |
| Photovoltaic solar cell with Polymer + | 198 | 191 | 194.5 |
| metal (3 wt. %), 70-μm film | | | |
| Photovoltaic solar cell without coating | 24 | 20 | 22 |
| film | | | |
| Photovoltaic solar cell with Polymer + | 41 | 37 | 39 |
| metal (1 wt. %), 60-μm film | | | |

It can be seen that the optimal conditions are obtained when the concentration of metal is 3-wt % and film thickness is 70 μm.

Integral characteristics of a photovoltaic solar cell device:
U₃₀₄=1130 MV
U saturation ˜5 V
R_{N}=1 MOhm
I₃₀₄˜5 μA
I measured <1 μA

It has been found that 3%-content of metal in a composite metal-polymer film provides a manifold increase in solar-cell efficiency.

$$\frac{η}{{η}_{0}} = 8.8 \frac{T ( λ )}{{T}^{( 0 )} ( λ )}$$

$$Thus \text{:}$$

$$\frac{η}{{η}_{0}} = {( \frac{T}{{T}^{( 0 )}} )}^{2} = 8.8 \frac{T}{{T}^{( 0 )}}$$

$$Therefore \text{:}$$

$$\frac{{T}^{( 0 )}}{T} = 8.8$$

In this case, efficiency of a photovoltaic solar cell device having electrical and physical properties presented in the measurement protocol can be expressed as follows.

η₀=0.871%

Thus, it becomes possible to reach the following efficiency due to the giant photovoltaic effect developed in a silicon photovoltaic solar cell device coated with a composite polymer-3% metal film.

η=67.45%.

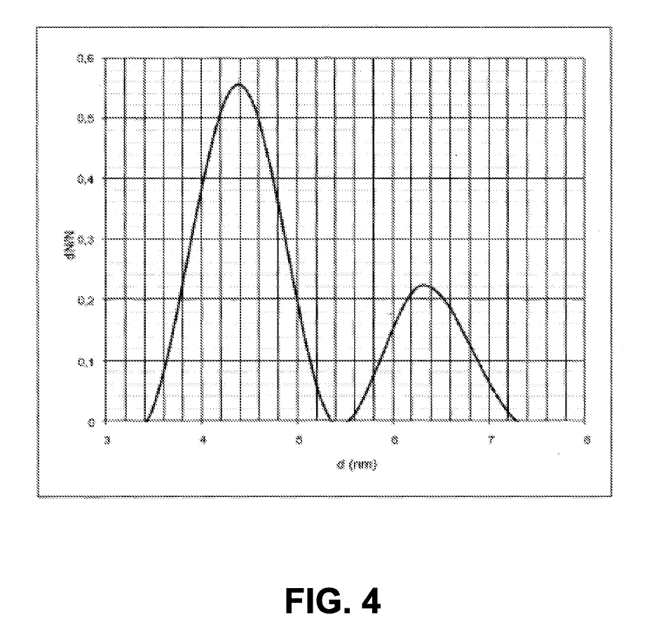

FIG. 4 shows results of measurements of particle-size dispersion conducted for the most efficient coatings. Particle size is plotted on the abscissa axis (see FIG. 4), with the ratio of particles of a predetermined diameter (dN) to the total number of the particle (N) plotted on the ordinate axis. The graph in FIG. 4 shows that for this particular film, the maximal number of particles has a diameter of approximately 4.5 nm. The next peak is obtained for particles having a diameter of approximately 6.3 nm.

Observations of the composite metal-containing polymer film of the invention under a transmission electron microscope showed that in the coating layer of the invention the particles are spherical in shape.

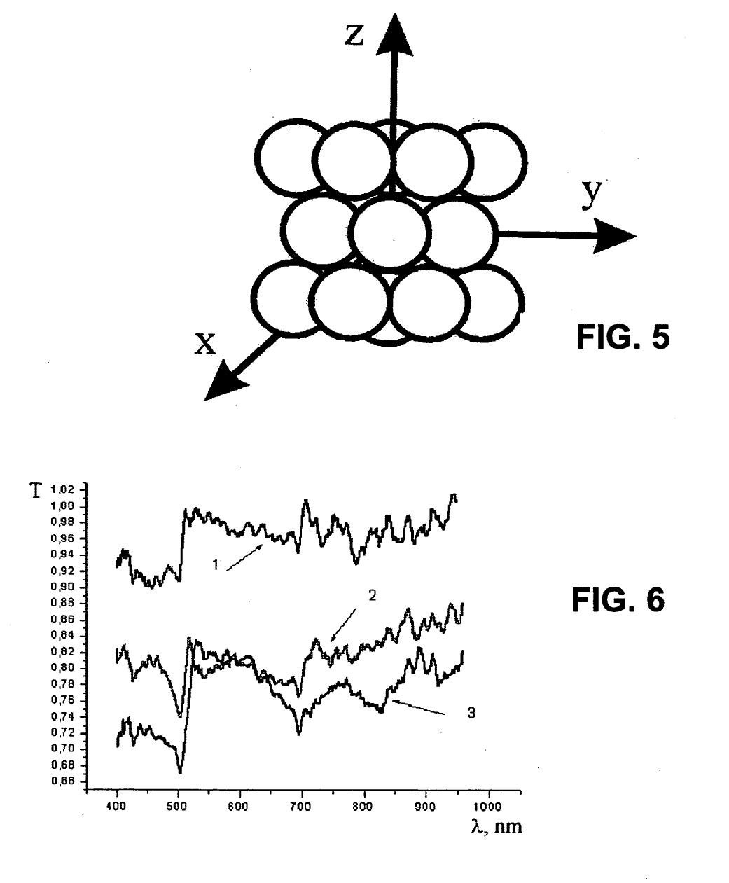

The exact mechanism of the giant photovoltaic effect provided by photovoltaic solar-cell devices of the invention coated with the above-described composite metal-polymer films is not known, but the inventors herein assume that the effect results from a specific configuration of metal particles that the inventors refer to as “a cluster structure.” More specifically, the particles are tightly packed into a structure, the model of which is shown in FIG. 5.

FIG. 5 shows a spherical-metal nanoparticle aggregate composed of spherical metal particles in a composite metal-polymer film. The aggregate contains 21 particles, and the reference point of coordinates is inside the aggregate.

The composite metal-polymer film has a thickness in the range of 10 to 100 μm. The composite film technique developed by the inventors makes it possible to obtain very thin films with thickness on the order of 100 nm.

FIG. 6 shows transmission spectra through a 50 μm-thick clean polymer film on a glass substrate and through the same film on the same substrate but with 10% metal content in the film. In the graph of FIG. 6, reference numeral 40 corresponds to a photovoltaic solar cell device specimen with a 50 μm-thick composite metal-polymer film on a glass substrate with metal nanoclusters in the film; reference numeral 42 corresponds to a glass substrate without the coating film; and reference numeral 44 corresponds to a glass substrate coated with the film but without metal nanoclusters. It can be seen that transmittance T becomes close to 1.

Based on the result of the analysis of these transmission spectra, one can conclude that introduction of metal nanoparticles having the above-described arrangement in polymer film converts this film into a super-transparent medium having in a wide range of an optical spectrum an absorption index on the order of 10⁻⁴.

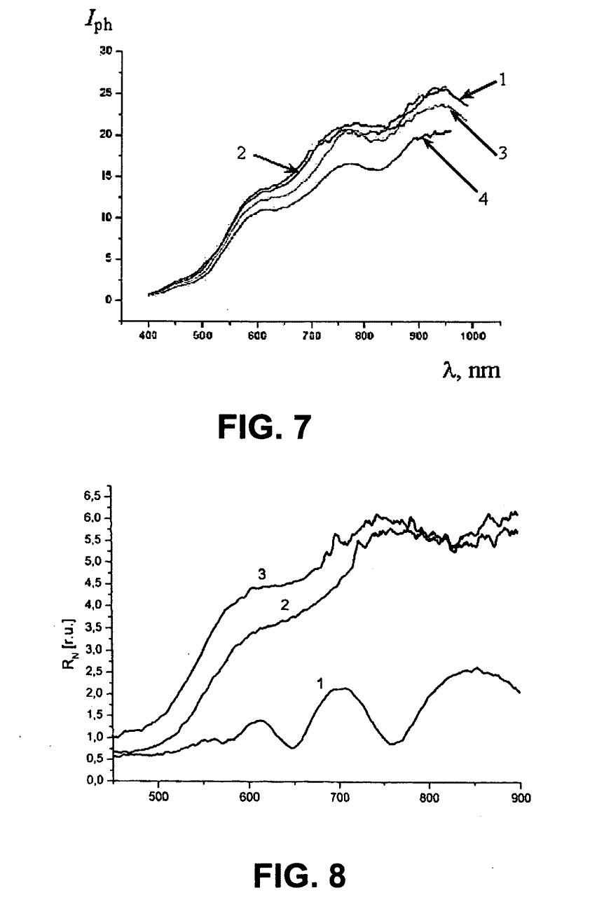

It is important to note that the coating film of the invention does not change the spectra of the initial irradiation. It can be seen from the graph in FIG. 7, which shows dependence of spectral signals Iₚₕ of a photocell from wavelength λ, that nothing is reflected from the coating film. In FIG. 7, the curve 46 corresponds to irradiation of a receiver, per se; the curve 48 corresponds to a 50-micron-thick metal-polymer coating film on a glass substrate having a thickness of 1 mm; the curve 50 corresponds to a 10-micron-thick metal-polymer coating film on a glass substrate having a thickness of 1 mm; and the curve 52 corresponds to a glass substrate having a thickness of 1 mm and having no coatings.

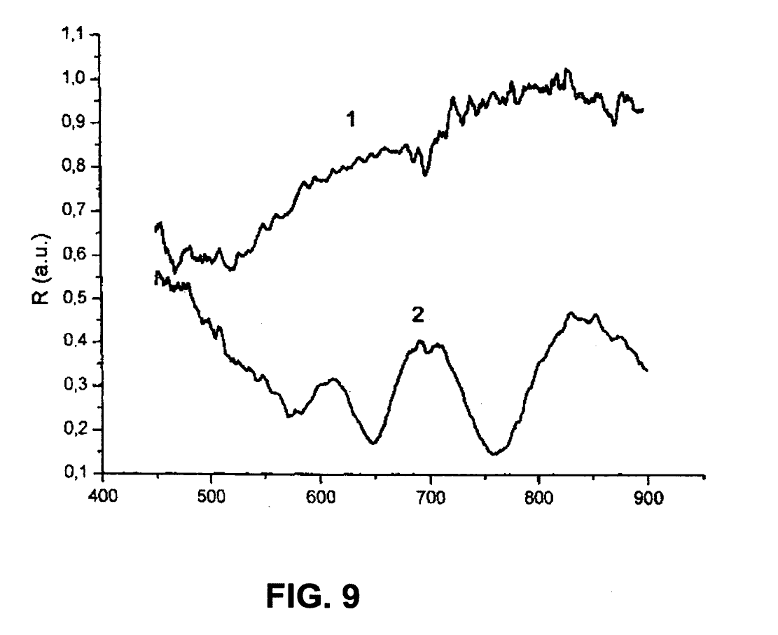

The film provides coefficient of refraction equal to 0.039. This value can be calculated from the coefficient of reflection shown in FIG. 8 and FIG. 9. In these drawings, wavelength λ is plotted in the abscissa axis, and reflectance is plotted on the ordinate axis; “r.u.” stands for “relative unit” and “a.u.” stands for “absolute unit”.

The principle of wideband antireflection on the basis of the new and transparent optical materials with quasi-zero values of indices of refraction and absorption is possible when the following condition is fulfilled.

$${r}_{12} = - {r}_{23} exp ( \frac{4 π}{λ} {n}_{2} {d}_{2} ) \vert$$

where for incidence of external light in the direction perpendicular to the surface, Frenel coefficients are expressed as follows.

$${r}_{12} = \frac{{n}_{1} - {n}_{2}}{{n}_{1} + {n}_{2}} , {r}_{23} = \frac{{n}_{2} - {n}_{3}}{{n}_{2} + {n}_{3}}$$

When absorption and refraction indices of a film from new (metal-polymer) materials reach zero value, such films can provide conditions of ideal optical refraction on the surfaces of optical media. The condition of ideal optical refraction is determined from the above equation.

$${r}_{12} = - {r}_{23} exp ( \frac{4 π}{λ} {n}_{2} {d}_{2} ) \vert$$

Under conditions of ideal optical antireflection, the amplitude of a reflected wave, and, hence, reflective capacity of the semi-infinitive medium surface, turns to zero.

Under conditions of ideal optical antireflection, the amplitude of an optical wave that penetrated the substrate is equal to the amplitude of an external wave under any angle of incidence.

If the substrate is transparent, i.e., comprises a low-absorption medium, then under conditions of ideal optical antireflection, a composite metal-polymer film becomes super-transparent, i.e., invisible to the viewer who looks at the film from above.

If the medium is absorptive, then under conditions of ideal optical antireflection, a viewer who looks at the coating film from above will perceive the substrate as a black body.

Under conditions of ideal optical antireflection, optical properties of the antireflective coating do not depend on optical properties of the substrate. This means that such an antireflective coating is universal and can be used to impart antireflective properties to surfaces of media made from various materials, including those with strong dispersion dependence from the dielectric constant.

Taking into account optical properties of the obtained composite metal-polymer film, it can be stated that nanomaterials of a new class can be synthesized, wherein by changing the arrangement of nanoparticles in the polymer film, it becomes possible to change the refraction index in a very wide range.

The giant photovoltaic effect observed by the inventors herein is based on the use of composite metal-polymer films that possess a low refraction index n and a low absorption index “k”. In other words: n≈0, k≈0

Thus, it has been shown that the invention provides a photovoltaic solar-cell device with a nanostructured coating that drastically improves efficiency of the photovoltaic solar-cell device due to active interaction of the elements of the nanostructured coating with photoelectronic processes that occur in the photovoltaic solar-cell device. The invention also provides a method for manufacturing a photovoltaic solar cell of high efficiency by coating the surface of a photovoltaic solar cell with a special coating that leads to a giant improvement in the efficiency of photovoltaic solar cells and that is universal for photovoltaic solar cells of different types.

Although the invention is described with reference to specific embodiments, these embodiments should not be construed as limiting the areas of application of the invention and that any changes and modifications are possible provided that these changes and modifications do not depart from the scope of the attached patent claims. For example, dielectric materials other than those mentioned in the specification and metals other than silver can be used in the method and device of the invention.

1. A solar-cell device with efficiency-improving nanocoating comprising: a photovoltaic solar cell and an antireflective coating film that is applied on the photovoltaic cell and interacts with a photovoltaic process of the photovoltaic cell, has a thickness ranging from 100 nm to 100 μm, and comprises a dielectric material that contains metal nanoparticles having dimensions from 4.5 to 10 nm and concentration ranging from 1 to 5%, said metal nanoparticles being organized into clusters.

2. The solar-cell device of claim 1, wherein said dielectric material is selected from glass, polymers, ceramics, and glass-ceramics, and the metal of the nanoparticles is a diamagnetic metal.

3. The solar-cell device of claim 2, wherein said diamagnetic metal is selected from the group consisting of silver, gold, cobalt, and chromium.

4. The solar-cell device of claim 1, wherein metal nanoparticles are spherical.

5. The solar-cell device of claim 3, wherein metal nanoparticles are spherical.

6. The solar-cell device of claim 1, wherein the photovoltaic solar cell comprises the following components listed in sequence of their arrangement: a substrate; a current take-off electrode placed onto the glass substrate; a p-type silicon plate placed onto the current take-off electrode; an n-type silicon plate placed onto the current take-off electrode; and a metal framing with front contacts placed onto the n-type silicon plate.

7. The solar-cell device of claim 6, wherein the diamagnetic metal of nanoparticles is silver, and the concentration of silver is 3-wt. %.

8. The solar-cell device of claim 5, wherein the photovoltaic solar cell comprises the following components listed in sequence of their arrangement: a substrate; a current take-off electrode placed onto the glass substrate; a p-type silicon plate placed onto the current take-off electrode; an n-type silicon plate placed onto the current take-off electrode; and a metal framing with front contacts placed onto the n-type silicon plate.

9. The solar-cell device of claim 8, wherein the diamagnetic metal of nanoparticles is silver, and the concentration of the silver is 3-wt. %.

10. The solar-cell device of claim 1, wherein the number of particles in a cluster ranges from 2 to 21.

11. The solar-cell device of claim 5, wherein the number of particles in a cluster ranges from 2 to 21.

12. The solar-cell device of claim 7, wherein the number of particles in a cluster ranges from 2 to 21.

13. The solar-cell device of claim 1, wherein the number of particles in a cluster is 21.

14. The solar-cell device of claim 5, wherein the number of particles in a cluster is 21.

15. The solar-cell device of claim 7, wherein the number of particles in a cluster is 21.

16. A method of manufacturing a photovoltaic solar-cell device with efficiency-improving nanocoating comprising the following steps:
providing a photovoltaic solar cell; and
coating the photovoltaic solar cell with a coating film that interacts with a photovoltaic process of the photovoltaic cell, has a thickness ranging from 100 nm to 100 μm, and comprises a dielectric material that contains metal nanoparticles having dimensions from 4.5 to 10 nm and concentration ranging from 1 to 5%, said metal nanoparticles being organized into clusters.

17. The method of claim 16, wherein said coating film is produced by preparing a polymer solution, providing a reactor, filling the reactor with said polymer solution, filling the reactor with an inert gas, heating the polymer solution in said reactor while intensively stirring the polymer solution, adding a solution of said metal nanoparticles to the polymer solution, carrying out a reaction at 110 to 250° C., filtering gaseous products of the reaction, extracting the reaction product with a solvent, dehydrating the product, and drying the product, thus forming said coating film.

18. The method of claim 16, wherein the number of nanoparticles in the cluster ranges from 2 to 21.
